(19) United States
(12) Patent Application Publication
(10) Pub. No.: US 2023/0028784 A1
(43) Pub. Date: Jan. 26, 2023

(54) DISPLAY DEVICE

(71) Applicant: Samsung Display Co., Ltd., Yongin-si (KR)

(72) Inventor: INYOUNG JUNG, Seoul (KR)

(21) Appl. No.: 17/719,769

(22) Filed: Apr. 13, 2022

(30) Foreign Application Priority Data
Jul. 26, 2021 (KR) 10-2021-0098056

(51) Int. Cl. H01L 51/52

(52) U.S. Cl. CPC H01L 51/5228; H01L 27/3246

(57) ABSTRACT

A display device includes a base substrate, a pixel defining film which is disposed on the base substrate and in which an opening is defined, a first electrode disposed on the base substrate and including a first surface facing the base substrate and a second surface opposite to the first surface and exposed in the opening, a light-emitting layer disposed on the first electrode in the opening, a hole transport region disposed between the first electrode and the light-emitting layer, an electron transport region disposed on the light-emitting layer, a second electrode disposed on the electron transport region and disposed extending above the pixel defining film, and a first auxiliary electrode disposed on the second electrode not to overlap the light-emitting layer and having a lower resistivity than a resistivity of the second electrode.

This application claims priority to Korean Patent Application No. 10-2021-0098056, filed on Jul. 26, 2021, and all the benefits accruing therefrom under 35 U.S.C. § 119, the content of which in its entirety is herein incorporated by reference.

### BACKGROUND

### 1. Field

Embodiments of the invention herein relate to a display device, and more particularly, to a display device including an auxiliary electrode.

### 2. Description of the Related Art

Various display devices used in multimedia equipment such as cellular phones, navigation systems, game consoles, tablet computers and televisions, are being developed. The display device has various wirings for displaying an image. When a current flows through the wiring by applying power to the display device, an image is displayed on a display device. In this case, a voltage drop may occur when a current passes through the wiring. The voltage drop may cause display quality of the display device to be deteriorated. Accordingly, studies on various methods of reducing the voltage drop in the display device are being conducted.

### SUMMARY

Embodiments of the invention provide a display device having a reduced voltage drop.

An embodiment of the invention provides a display device including a base substrate, a pixel defining film which is disposed on the base substrate and in which an opening is defined therein, a first electrode disposed on the base substrate and including a first surface facing the base substrate and a second surface opposite to the first surface and exposed in the opening, a light-emitting layer disposed on the first electrode in the opening, a hole transport region disposed between the first electrode and the light-emitting layer, an electron transport region disposed on the light-emitting layer, a second electrode disposed on the electron transport region and disposed extending above the pixel defining film, and a first auxiliary electrode disposed on the second electrode not to overlap the light-emitting layer, and having a lower resistivity than a resistivity of the second electrode

In an embodiment, the first auxiliary electrode may have a resistivity greater than about 0 ohm centimeter (Ωcm) and equal to or less than about 4.4×10⁻⁶ ωcm.

In an embodiment, the first auxiliary electrode may include silver (Ag) or copper (Cu).

In an embodiment, the hole transport region and the electron transport region may be disposed extending above the pixel defining film.

In an embodiment, the display device may further include a second auxiliary electrode disposed on the base substrate and including a first surface facing the base substrate and a second surface opposite to the first surface and exposed in a contact hole, where an auxiliary opening may be defined on the pixel defining film to overlap the first auxiliary electrode, and the contact hole may be defined by penetrating the hole transport region and the electron transport region extending to an inside of the auxiliary opening.

In an embodiment, the second electrode in the auxiliary opening may be disposed directly on the second auxiliary electrode.

In an embodiment, the first auxiliary electrode may charge the auxiliary opening.

In an embodiment, the display device may further include an intermediate auxiliary electrode disposed between the second auxiliary electrode and the second electrode in the auxiliary opening, and having a lower resistivity than the resistivity of the second electrode.

In an embodiment, the display device may further include an intermediate auxiliary electrode charging the auxiliary opening and having a lower resistivity than the resistivity of the second electrode, where the second electrode may be disposed directly on the intermediate auxiliary electrode.

In an embodiment of the invention, a display device includes a plurality of pixel groups which are arranged in a first direction and separated from each other, and each of which includes a plurality of light-emitting regions arranged in a second direction perpendicular to the first direction, a base substrate, a pixel defining film which is disposed on the base substrate and in which an opening corresponding to each of the plurality of light-emitting regions is defined, a first electrode disposed on the base substrate and patterned corresponding to each of the plurality of light-emitting regions, a light-emitting layer disposed on the first electrode substrate and patterned corresponding to each of the plurality of light-emitting regions, a hole transport region disposed between the first electrode and the light-emitting layer, an electron transport region disposed on the light-emitting layer, a second electrode disposed on the electron transport region, and at least one first auxiliary electrode disposed on the second electrode not to overlap the light-emitting layer, and having a lower resistivity than a resistivity of the second electrode.

In an embodiment, in a plan view, the at least one first auxiliary electrode may be disposed between the plurality of pixel groups, and the at least one first auxiliary electrode may have a line shape extending in the second direction.

In an embodiment, the at least one first auxiliary electrode may be provided in plural, the plurality of first auxiliary electrodes respectively arranged between the plurality of pixel groups, the first auxiliary electrodes respectively may include sub-auxiliary electrodes separated from each other in the second direction, and the first auxiliary electrodes may each have a dot shape.

In an embodiment, the at least one first auxiliary electrode may be provided in plural, and in a plan view, the at least one first auxiliary electrodes may be separated in the first direction with at least one of the plurality of pixel groups disposed therebetween.

In an embodiment, the plurality of light-emitting regions may include a first light-emitting region emitting first light, a second light-emitting region emitting second light having a wavelength different from a wavelength of the first light, and a third light-emitting region emitting third light having a wavelength different from the wavelengths of the first light and the second light, the plurality of light-emitting regions being alternately arranged in an order of the first light-emitting region to the third light-emitting region in respective pixel groups of the plurality of pixel groups.

In an embodiment, the plurality of pixel groups may each include light-emitting regions of the plurality of light-emitting regions and a non-light-emitting region disposed between the light-emitting regions, and the hole transport region, the electron transport region and the second electrode may be disposed as a common layer in the light-emitting regions and the non-light-emitting region.

In an embodiment of the invention, a display device in which a plurality of light-emitting regions and a non-light-emitting region disposed between the plurality of light-emitting regions are defined includes a base substrate, a pixel defining film which is disposed on the base substrate and in which an opening corresponding to each of the plurality of light-emitting regions is defined, a first electrode disposed on the base substrate by being patterned corresponding to each of the plurality of light-emitting regions and including a first surface facing the base substrate and a second surface opposite to the first surface and exposed in the opening, a light-emitting layer disposed on the first electrode substrate, a hole transport region disposed between the first electrode and the light-emitting layer, an electron transport region disposed on the light-emitting layer, a second electrode disposed as a common layer in the light-emitting region and the non-light-emitting region and a first auxiliary electrode disposed on the second electrode in the non-light-emitting region and having a lower resistivity than a resistivity of the second electrode.

In an embodiment, the hole transport region and the electron transport region may be disposed as a common layer in the plurality of light-emitting regions and the non-light-emitting region.

In an embodiment, the display device may further include a second auxiliary electrode separated from the first electrode on the base substrate and disposed in a same layer as a layer in which the first electrode is disposed.

In an embodiment, an auxiliary opening may be defined in the pixel defining film to overlap the first auxiliary electrode, a contact hole may be defined to penetrate the hole transport region and the electron transport region extending to an inside of the auxiliary opening, and the second electrode may be disposed directly on a first surface of the second auxiliary electrode in the contact hole, the first surface of the second auxiliary electrode facing a second surface of the second auxiliary electrode facing the base substrate.

In an embodiment, the display device may further include an intermediate auxiliary electrode disposed between the second auxiliary electrode and the second electrode, and having a lower resistivity than the resistivity of the second electrode.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a perspective view of an embodiment of an electronic device;

FIG. 2 is a perspective view of an embodiment of a display device;

FIG. 3A is a plan view of an embodiment of a display device;

FIG. 3B is a plan view of an embodiment of a display device;

FIG. 4 is a drawing schematically illustrating an embodiment of a manufacturing method of a portion of a display device;

FIG. 5 is a cross-sectional view of an embodiment of a display device;

FIG. 6 is a cross-sectional view of an embodiment of a display device;

FIG. 7 is a cross-sectional view of an embodiment of a display device;

FIG. 8 is a cross-sectional view of an embodiment of a display device;

FIG. 9 is a perspective view of an embodiment of a display device;

FIG. 10 is a plan view of an embodiment of a display device.

### DETAILED DESCRIPTION

It will be understood that when an element or layer is referred to as being “on”, “connected to” or “coupled to” another element or layer, it can be directly on, connected or coupled to the other element or layer or intervening elements or layers may be present.

Like reference numerals or symbols refer to like elements throughout. The thickness and the ratio and the dimension of the element are exaggerated for effective description of the technical contents. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another element(s) or feature(s) as illustrated in the drawing figures. It will be understood that the spatially relative terms are intended to encompass different orientations of the device in use or operation in addition to the orientation depicted in the drawing figures.

It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display device in an embodiment of the invention will be explained in detail with reference to the accompanying drawings.

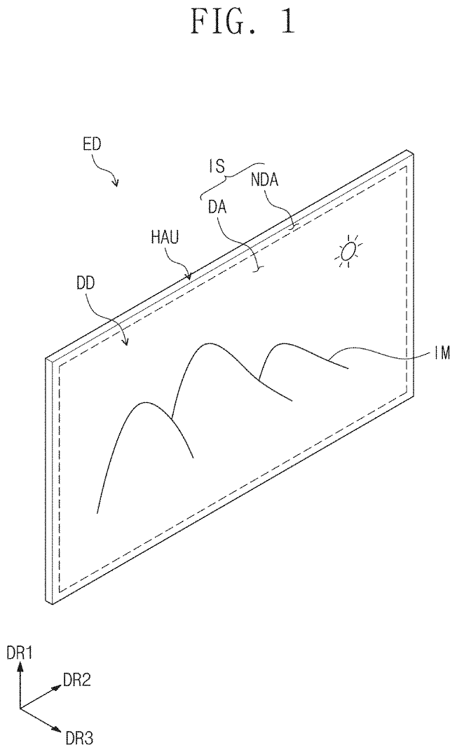

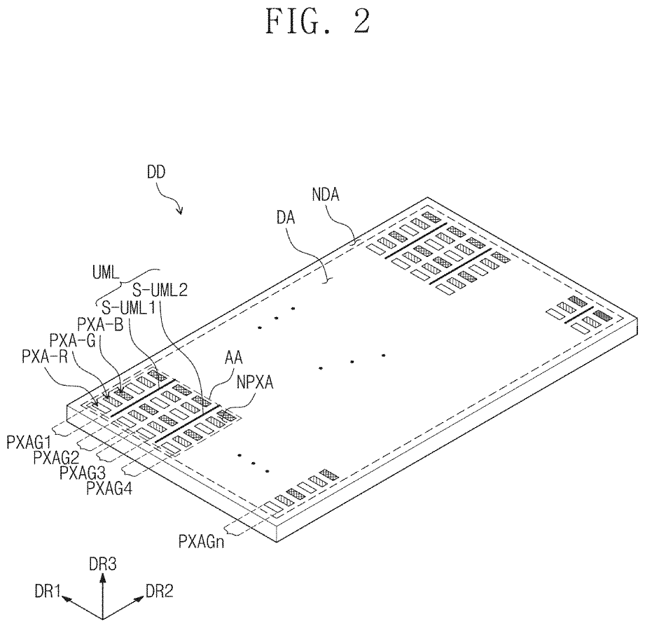

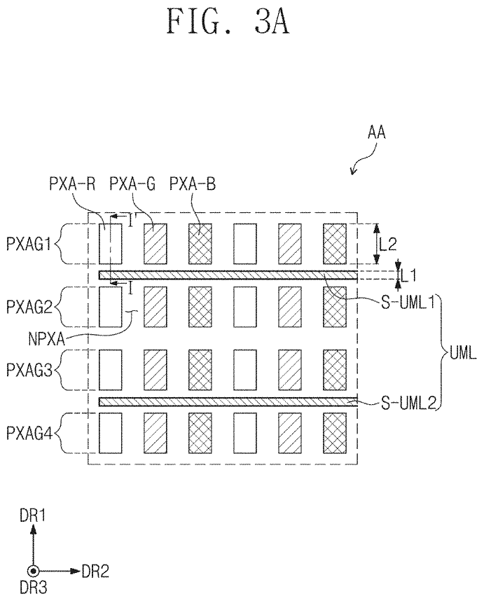

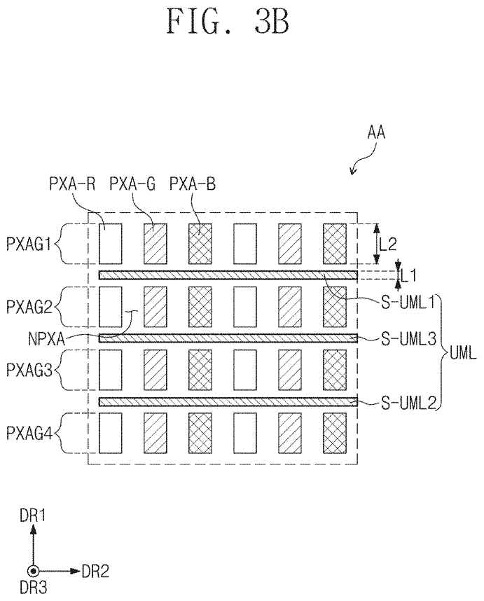

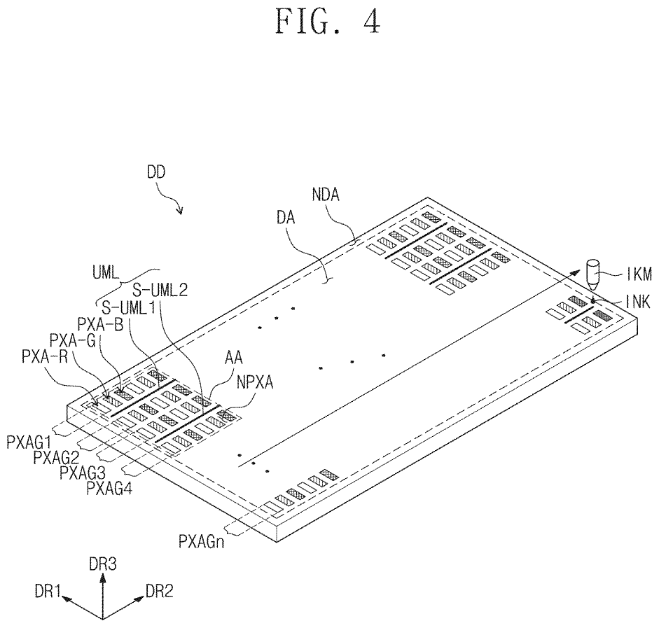

FIG. 1 is a perspective view of an embodiment of an electronic device. FIG. 2 is a perspective view of an embodiment of a display device. FIG. 3A is an enlarged view of an embodiment of a portion of a display device. FIG. 3B is an enlarged view of an embodiment of a portion of a display device. FIGS. 3A and 3B may each illustrate an enlarged plan view of a portion corresponding to region AA in FIG. 2. FIG. 4 is a perspective view illustrating an embodiment of a manufacturing method of a portion of a display device.

Referring to FIG. 1, in an embodiment, an electronic device ED may be a large-sized electronic device such as a television, a monitor, or an outdoor billboard. In addition, the electronic device ED may be a medium- and small-sized electronic device such as a personal computer, a laptop computer, a personal digital terminal, a car navigation unit, a game console, a smartphone, a tablet, or a camera. In addition, these are only suggested as examples, and other electronic devices may be employed as long as not deviating from the invention.

The electronic device ED may include a display device DD and a housing HAU. The housing HAU may accommodate the display device DD. The housing HAU may be disposed to cover the display device DD such that a top surface which is a display surface IS of the display device DD is exposed. The housing HAU may cover a side surface and a bottom surface of the display device DD, while exposing the entire top surface. However, the invention is not limited thereto, and the housing HAU may cover a portion of the top surface as well as the side surface and the bottom surface of the display device DD.

In FIG. 1 and the following drawings, a first directional axis DR1 to a third directional axis DR3 are illustrated, and the directions indicated by the first to third directional axes DR1, DR2, DR3 have relative concept and may be changed to other directions. In addition, the directions indicated by the first to third directional axes DR1, DR2, DR3 may be explained as first to third directions, and thus the same reference numerals or symbols may be used. In this specification, the first directional axis DR1 and the second directional axis DR2 are perpendicular to each other, the third directional axis DR3 is a normal direction of a plane defined by the first directional axis DR1 and the second directional axis DR2.

In this specification, the thickness direction of the electronic device ED or the display device DD, is parallel to the third direction DR3 which is a normal direction of a plane defined by the first direction DR1 and the second direction DR2. In this specification, the front surface (or top surface) and rear surface (or bottom surface) of each member constituting the display device DD may be defined on basis of the third direction DR3.

In FIG. 1, in an embodiment, a display surface IS of the electronic device ED is illustrated as being parallel to a plane defined by the first directional axis DR1 and the second directional axis DR2 which crosses the first directional axis DR1. However, this is mere an example, and the display surface IS of the electronic device ED in an embodiment may have a curved shape.

The display device of an embodiment may include a display region DA and a non-display region NDA adjacent to the display region DA. The display region DA corresponds to a region in which an image IM is displayed.

In an embodiment, the display region DA may have a quadrangular (e.g., rectangular) shape. The non-display region NDA may enclose the display region DA. However, the invention is not limited thereto, and the shape of the display region DA and the shape of the non-display region NDA may be designed relatively. In addition, the non-display region NDA may not exist on the display surface IS which is the front surface of the display device DD.

Referring to FIG. 2 to FIG. 3B, the display device DD in an embodiment may include a plurality of light-emitting regions PXA-R, PXA-G and PXA-B. FIG. 2 to FIG. 3B are plan views of the display device DD in which an encapsulation layer TFE is not provided yet. The display device DD in an embodiment may include the first to third light-emitting regions PXA-R, PXA-G, and PXA-B. In an embodiment, the display device DD according to may include a first light-emitting region PXA-R, a second light-emitting region PXA-G, and a third light-emitting region PXA-B which are separated from each other, for example. In an embodiment, the first light-emitting region PXA-R may be a red light-emitting region in which red light is emitted, a second light-emitting region PXA-G may be a green light-emitting region in which green light is emitted, and the third light-emitting region PXA-B may be a blue light-emitting region in which blue light is emitted.

The first to third light-emitting regions PXA-R, PXA-G and PXA-B may be separated from each other and may not overlap each other, in a plan view. In an embodiment, the non-light-emitting region NPXA may be disposed between the neighboring light-emitting regions PXA-R, PXA-G and PXA-B, for example.

FIG. 2 to FIG. 3B illustrate that the light-emitting regions PXA-R, PXA-G and PXA-B of the display device DD in an embodiment are arranged in a stripe shape. In other words, a plurality of first light-emitting regions PXA-R, a plurality of second light-emitting regions PXA-G and a plurality of third light-emitting regions PXA-B in the display device DD in an embodiment illustrated in FIG. 2 may be arranged along the first direction DR1. In addition, the plurality of light-emitting regions may be alternately arranged in order of the first light-emitting region PXA-R, the second light-emitting region PXA-G and the third light-emitting region PXA-B along the second directional axis DR2.

The arrangement of the light-emitting regions PXA-R, PXA-G and PXA-B is not limited to that illustrated in FIG. 2, and the arrangement order of the first light-emitting region PXA-R, the second light-emitting region PXA-G and the third light-emitting region PXA-B may be provided in various combinations according to the properties of display quality desired for the display device DD. In an embodiment, the light-emitting regions PXA-R, PXA-G and PXA-B emitting light having different wavelengths from each other, among the plurality of light-emitting regions PXA-R, PXA-G and PXA-B, may have the same area as each other. In this case, the area may be an area as seen from above a plane defined by the first direction DR1 and the second direction DR2 (hereinafter referred to as “in a plan view”). However, the invention is not limited thereto. Each of the light-emitting region may have different areas. In addition, the area ratio between the light-emitting regions may be controlled variously according to the properties of display quality desired for the display device DD, and the shapes of the light-emitting regions PXA-R, PXA-G and PXA-B in a plan view may be modified variously and provided.

The display device DD may include n (n is an integer equal to or greater than 2) pixel groups PXAG1, PXAG2, PXAG3, PXAG4, . . . , PXAGn. The light-emitting regions may be alternately arranged in one row along the second direction DR2 in an order of the first light-emitting region PXA-R, the second light-emitting region PXA-G, the third light-emitting region PXA-B in each of the pixel groups PXAG1, PXAG2, PXAG3, PXAG4, . . . , PXAGn. Hereinafter, the group of the light-emitting group PXA-R, PXA-G and PXA-B arranged in one row along the second direction DR2 is defined as one pixel group. In a plan view, the pixel groups PXAG1, PXAG2, PXAG3, PXAG4, . . . , PXAGn may be arranged to be spaced apart from each other in the first direction DR1. In a plan view defined by the first direction DR1 and the second direction DR2, each of the pixel groups PXAG1, PXAG2, PXAG3, PXAG4, . . . , PXAGn may include the non-light-emitting region NPXA disposed between the light-emitting regions PXA-R, PXA-G and PXA-B. The non-light-emitting region NPXA may be disposed between the pixel groups PXAG1, PXAG2, PXAG3, PXAG4, . . . , PXAGn.

In an embodiment, the display device DD may include an upper auxiliary electrode UML disposed between the pixel groups PXAG1, PXAG2, PXAG3, PXAG4, . . . , PXAGn in a plan view. The upper auxiliary electrode may be a line shape extending in the second direction DR2 in a plan view. The width of the upper auxiliary electrode UML in the first direction DR1 in a plan view may be less than the width of each of the pixel groups PXAG1, PXAG2, PXAG3, PXAG4, . . . , PXAGn.

The upper auxiliary electrode UML may include a plurality of upper auxiliary electrodes S-UML1 and S-UML2. As illustrated in FIG. 3A, the upper auxiliary electrodes S-UML1 and S-UML2 may be alternately arranged between the pixel groups PXAG1, PXAG2, PXAG3, PXAG4, . . . , PXAGn. As illustrated in FIG. 3B, the upper auxiliary electrodes S-UML1, S-UML3 and S-UML2 may be continuously arranged between the pixel groups PXAG1, PXAG2, PXAG3, PXAG4, . . . , PXAGn. However, this is a mere example, and the invention is not limited thereto. In an embodiment, the upper auxiliary electrode UML may be arranged in at least one region between the pixel groups PXAG1, PXAG2, PXAG3, PXAG4, . . . , PXAGn, or may be randomly arranged between the pixel groups PXAG1, PXAG2, PXAG3, PXAG4, . . . , PXAGn, for example. In other words, at least one of pixel groups PXAG1, PXAG2, PXAG3, PXAG4, . . . , PXAGn may be arranged between the first upper auxiliary electrode S-UML1 and the second upper auxiliary electrode S-UML2. In an embodiment of FIG. 3A, a width L1 of each of the upper auxiliary electrodes S-UML1 and S-UML2 in the first direction DR1 may be less than a width L2 of each of the pixel groups PXAG1, PXAG2, PXAG3, PXAG4, . . . , PXAGn in the first direction DR1, but the invention is not limited thereto. Similarly, in an embodiment of FIG. 3B, a width L1 of each of the upper auxiliary electrodes S-UML1, S-UML2 and S-UML3 in the first direction DR1 may be less than a width L2 of each of the pixel groups PXAG1, PXAG2, PXAG3, PXAG4, . . . , PXAGn in the first direction DR1, but the invention is not limited thereto.

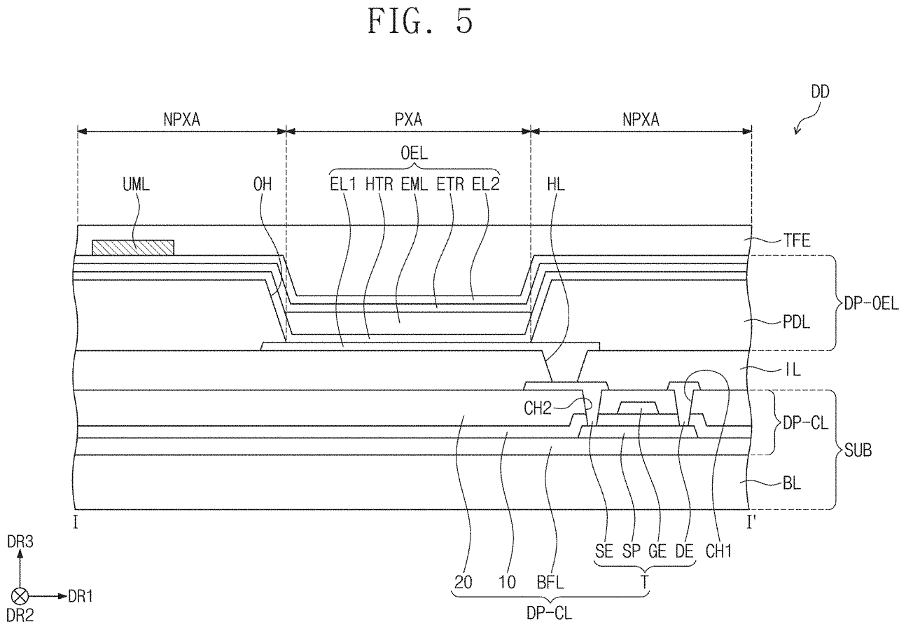

Referring to FIG. 4, the upper auxiliary electrode UML may be provided by an ink jet printing method. FIG. 4 is a plan view of the display device DD in which an encapsulation layer TFE is not provided yet. In an embodiment, the upper auxiliary electrode UML may be formed or provided by causing an ink application part IKM disposed on the upper side of the non-light-emitting region NPXA between pixel groups PXAG1, PXAG2, PXAG4, . . . , PXAGn to move in parallel to the second direction DR2 and applying an electrode-forming ink INK to the non-light-emitting region NPXA, for example. The electrode-forming ink INK may be provided on a second electrode EL2 (refer to FIG. 5) to be described later.

The electrode-forming ink INK may include a solvent and a metal material dispersed in the solvent. In an embodiment, the metal material may include silver (Ag) or copper (Cu). Though not illustrated in the drawings, the applied electrode-forming ink INK is subjected to a first heat treatment at about 50 degrees Celsius (° C.) and then a second heat treatment at about 170° C. so as to volatilize the solvent, thereby forming the upper auxiliary electrode UML.

FIG. 5 is a cross-sectional view of an embodiment of a display device DD. FIG. 5 may be a cross-sectional view of a portion taken along line I-I′ in FIG. 3A.

Referring to FIG. 5, the display device DD may include the base substrate SUB, the insulating layer IL, the display element layer DP-OEL, the upper auxiliary electrode UML and the encapsulation layer TFE.

The base substrate SUB of the display device DD in an embodiment may include a base layer BL and a circuit layer DP-CL disposed on the base layer BL. The base layer BL may provide a base surface on which the circuit layer DP-CL and a light-emitting element OEL are disposed. The base layer BL may be a glass substrate, a metal substrate, or a plastic substrate. However, the invention is not limited thereto, and the base layer BL may be an inorganic layer, an organic layer or a composite material layer including the organic material and the inorganic material.

In an embodiment, the circuit layer DP-CL may be disposed on the base layer BL, and include a buffer layer BFL as an inorganic film. The buffer layer BFL may prevent from impurities diffusing to a transistor T. The buffer layer BFL may include at least one of silicon nitride (SiNx), silicon oxide (SiOx), or silicon oxynitride (SiOxNy). In another embodiment, the buffer layer BFL may be omitted and the transistor T may be disposed directly on the base layer BL.

In an embodiment, a semiconductor pattern SP of the transistor T may be disposed on the buffer layer BFL. The semiconductor pattern SP may include amorphous silicon, polysilicon, or metal oxide. A first intermediate insulating layer 10 may be disposed on the semiconductor pattern SP. A control electrode GE may be disposed on the first intermediate insulating layer 10. The first intermediate insulating layer 10 may include an organic material, an inorganic material, or a combination thereof.

A second intermediate insulating layer 20 which covers the control electrode GE may be disposed on the first intermediate insulating layer 10. The second intermediate insulating layer 20 may include an organic material, an inorganic material, or a combination thereof.

An input electrode DE and an output electrode SE may be disposed on the second intermediate insulating layer 20. The input electrode DE and the output electrode SE may be connected to the semiconductor pattern SP respectively through a first lower contact hole CH1 and a second lower contact hole CH2 penetrating the first intermediate insulating layer 10 and the second intermediate insulating layer 20.

The insulating layer IL may be disposed on the base substrate SUB including the circuit layer DP-CL. The insulating layer IL may cover the input electrode DE and the output electrode SE. A hole HL may be defined in the insulating layer IL. In addition, the insulating layer IL, excluding a portion in which the hole HL is defined, may provide a flat surface to the circuit layer DP-CL. The insulating layer IL may include an organic material. In an embodiment, the insulating layer IL may include polyimide, etc., for example. The hole HL defined in the insulating layer IL may be a via-hole by penetrating the insulating layer. The insulating layer IL may have a stepped region by having the height difference between a portion of the hole HL and the flat surface.

The display element layer DP-OEL may be disposed on the circuit layer DP-CL. The display element layer DP-OEL may be disposed on the insulating layer IL. The display element layer DP-OEL may include the pixel defining film PDL and the light-emitting element OEL.

The pixel defining film PDL may correspond to the non-light-emitting region NPXA. An opening OH corresponding to the light-emitting region PXA may be defined in the pixel defining film PDL. In an embodiment, an opening OH corresponding to each of the plurality of light-emitting regions PXA-R, PXA-G and PXA-B (refer to FIG. 3A) may be defined in the pixel defining film PDL, for example.

The light-emitting element OEL may include a first electrode EL1, a hole transport region HTR, a light-emitting layer EML, an electron transport region ETR and a second electrode EL2.

The first electrode EL1 may be disposed on the base substrate SUB. The first electrode EL1 may be electrically connected to the output electrode SE through the hole HL. The first electrode EL1 of the light-emitting element OEL and the output electrode SE are electrically connected to each other, and thus the light-emitting element may be driven.

The first electrode EL1 may have a top surface exposed in the opening OH. The first electrode EL1 may correspond to the light-emitting region PXA. The first electrode EL1 may be patterned corresponding to the plurality of light-emitting regions PXA-R, PXA-G and PXA-B (refer to FIG. 3A).

The first electrode EL1 has conductivity. The first electrode EL1 may include a metal material, a metal alloy, or a conductive compound. The first electrode EL1 may be an anode or a cathode. However, the invention is not limited thereto. In an embodiment, the first electrode EL1 may be a pixel electrode. The first electrode EL1 may be a transmissive electrode, a transflective electrode, or a reflective electrode. When the first electrode EL1 is the transmissive electrode, the first electrode EL1 may include a transparent metal oxide such as indium tin oxide (“ITO”), indium zinc oxide (“IZO”), zinc oxide (ZnO), and indium tin zinc oxide (“ITZO”). When the first electrode EL1 is the transflective electrode or the reflective electrode, the first electrode EL1 may include Ag, Mg, Cu, Al, Pt, Pd, Au, Ni, Nd, Ir, Cr, Li, Ca, Mo, Ti, W, a compound thereof, or a combination thereof (e.g., a combination of Ag and Mg). In an alternative embodiment, the first electrode EL1 may have a multilayer structure including a reflective layer or transflective layer including the above materials, and a transparent conductive layer including ITO, IZO, ZnO, ITZO or the like. In an embodiment, the first electrode EL1 may have a three-layer structure of ITO/Ag/ITO, for example, but is not limited thereto. In addition, the invention is not limited thereto. The first electrode EL1 may include the metal material described above, a combination of at least two metal materials selected from the metal materials described above, or oxides of the metal materials described above.

The light-emitting layer EML may be disposed on the first electrode EL1 in the opening OH. The light-emitting layer EML may correspond to the light-emitting region PXA. The light-emitting layer EML may be patterned corresponding to the plurality of light-emitting regions PXA-R, PXA-G and PXA-B (refer to FIG. 3A).

The light-emitting layer EML may have a single layer including a single material, a single layer including a plurality of different materials, or a multilayer structure having a plurality of layers including a plurality of different materials. The light-emitting layers EML corresponding to the respective light-emitting regions PXA-R, PXA-G and PXA-B may include the same material or different materials. In an embodiment, when the light-emitting layers EML corresponding to the respective light-emitting regions PXA-R, PXA-G and PXA-B may include the same material, the light-emitting layers EML may all include a light-emitting material which emits blue light, for example. When the light-emitting layers EML corresponding to the respective light-emitting regions PXA-R, PXA-G and PXA-B may include materials different from each other, the light-emitting layers EML may include light-emitting materials which emit light of different colors.

The hole transport region HTR may be disposed between the first electrode EL1 and the light-emitting layer EML. The hole transport region HTR may be disposed extending above the pixel defining film PDL. The hole transport region HTR may be disposed as a common layer in the light-emitting region PXA and the non-light-emitting region NPXA. However, this is a mere example, and the invention is not limited thereto. The hole transport region HTR may be provided by being patterned in the opening OH which is defined in the pixel defining film PDL.

The hole transport region HTR may have a single layer including a single material, a single layer including a plurality of different materials, or a multilayer structure having a plurality of layers including a plurality of different materials.

The electron transport region ETR may be disposed above the light-emitting layer EML. The electron transport region ETR may be disposed extending above the pixel defining film PDL. The electron transport region ETR may be disposed as a common layer in the light-emitting region PXA and the non-light-emitting region NPXA. However, this is a mere example, and the invention is not limited thereto. The electron transport region ETR may be provided by being patterned in the opening OH which is defined in the pixel defining film PDL.

The electron transport region ETR may have a single layer including a single material, a single layer including a plurality of different materials, or a multilayer structure having a plurality of layers including a plurality of different materials. In an embodiment, the electron transport region ETR may have a single-layer structure of an electron injection layer (not illustrated) or an electron transport layer (not illustrated), or a single-layer structure including an electron injection material and an electron transport material, for example.

The second electrode EL2 may be disposed on the electron transport region ETR. The second electrode EL2 may be disposed extending above the pixel defining film PDL. The second electrode EL2 may be disposed as a common layer in the light-emitting region PXA and the non-light-emitting region NPXA. In other words, the second electrode EL2 may be disposed as a common layer to cover the non-light-emitting region NPXA between the pixel groups PXAG1, PXAG2, PXAG4, . . . , PXAGn (refer to FIG. 3A) and the pixel groups PXAG1, PXAG2, PXAG4, . . . , PXAGn (refer to FIG. 3A).

The second electrode EL2 may be a cathode or an anode, but the invention is not limited thereto. In an embodiment, when the first electrode EL1 is an anode, the second electrode EL2 may be a cathode, and when the first electrode EL1 is a cathode, the second electrode EL2 may be an anode, for example.

The second electrode EL2 may be a transmissive electrode, a transflective electrode, or a reflective electrode. When the second electrode EL2 is the transmissive electrode, the second electrode EL2 may include a transparent metal oxide such as ITO, IZO, zinc oxide (ZnO), and ITZO.

When the second electrode EL2 is the transflective electrode or the reflective electrode, the second electrode EL2 may include Ag, Mg, Cu, Al, Pt, Pd, Au, Ni, Nd, Ir, Cr, Li, Ca, Mo, Ti, Yb, W, a compound or combination including the same (e.g., AgMg, AgYb, or MgAg). In an alternative embodiment, the second electrode EL2 may be a structure having a multilayer structure including a reflective layer or a transflective layer including the above materials, and a transparent conductive layer including ITO, IZO, ZnO, ITZO or the like. In an embodiment, the second electrode EL2 may include the metal material described above, a combination of at least two metal materials selected from the metal materials described above, or oxides of the metal materials described above, for example.

The upper auxiliary electrode UML may be disposed on the second electrode EL2 extending in the non-light-emitting region NPXA. The upper auxiliary electrode UML may not overlap the light-emitting region PXA. In other words, the upper auxiliary electrode UML may not overlap the light-emitting layer EML and the first electrode EL1. The upper auxiliary electrode UML may overlap the non-light-emitting region NPXA. In other words, the upper auxiliary electrode UML may overlap the hole transport region HTR and the electron transport region ETR which extend in the non-light-emitting region NPXA.

The upper auxiliary electrode UML may have a lower resistivity than that of the second electrode EL2. The upper auxiliary electrode UML may have a resistivity greater than about 0 ohm centimeter (ωcm) and equal to or less than about 4.4×10⁻⁶ ωcm. In an embodiment, the upper auxiliary electrode UML may have a resistivity of about 2.1×10⁻⁶ ωcm to about 4.4×10⁻⁶ ωcm, for example. The upper auxiliary electrode UML may include silver or copper. However, this is a mere example, and the invention is not limited thereto. The upper auxiliary electrode UML may include another metal material which has a lower resistivity than that of the second electrode EL2.

In the display device DD in an embodiment, the second electrode EL2 and the upper auxiliary electrode UML having a lower resistivity than that of the second electrode EL2 may be electrically connected to each other, and the resistance of the second electrode EL2 may thus be lowered, thereby reducing a voltage drop (“IR drop”) which occurs in the second electrode EL2. The reduction of the voltage drop in the second electrode EL2 leads to a decrease in stain which appears by the voltage drop in the display region DA (refer to FIG. 1), thereby improving the display quality of the display device DD.

The encapsulation layer TFE may cover the light-emitting element OEL. The encapsulation layer TFE may encapsulate the display element layer DP-OEL. The encapsulation layer TFE may be a thin-film encapsulation layer. The encapsulation layer TFE may be a single layer or a plurality of layers stacked. The encapsulation layer TFE may include at least one insulating layer. The encapsulation layer TFE in an embodiment may include at least one inorganic layer (hereinafter, encapsulation inorganic layer). In addition, the encapsulation layer TFE in an embodiment may include at least one organic layer (hereinafter, encapsulation organic layer) and at least one encapsulation inorganic layer.

The encapsulation inorganic layer protects the display element layer DP-OEL from moisture/oxygen, and the encapsulation organic layer protects the display element layer DP-OEL from foreign materials such as dust particles. The encapsulation inorganic layer may include a silicon nitride, a silicon oxynitride, a silicon oxide, a titanium oxide, or an aluminum oxide, but is not particularly limited thereto. The encapsulation organic layer may include an acrylic compound and an epoxy compound. The encapsulation organic layer may include a photopolymerizable organic material, but is not particularly limited thereto.

The encapsulation layer TFE may be disposed on the second electrode EL2 and may be disposed to fill the opening OH.

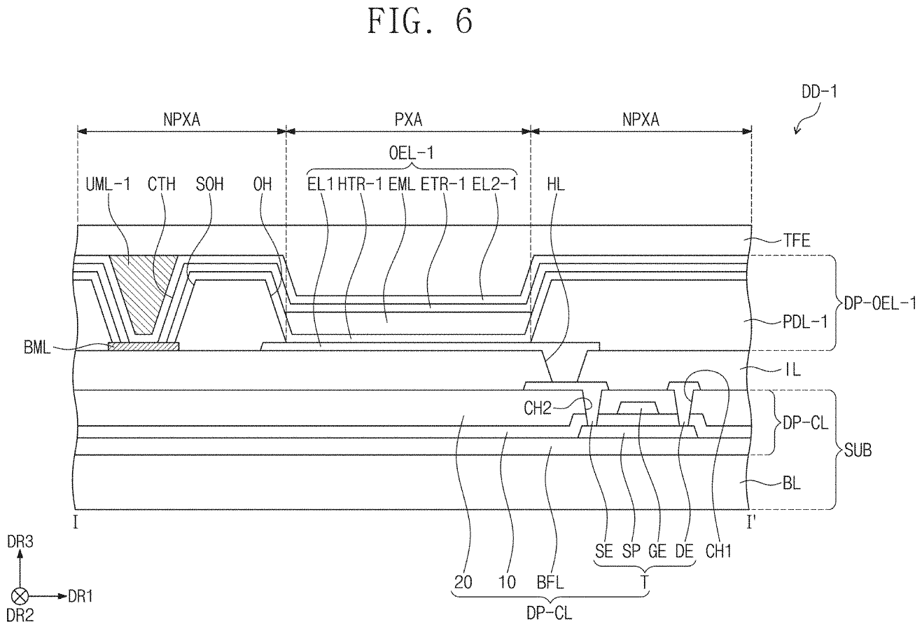

FIG. 6 to FIG. 8 are cross-sectional views of an embodiment of display devices DD-1, DD-2 and DD3. FIG. 6 to FIG. 8 may be cross-sectional views of a portion taken along line I-I′ in FIG. 3A. In the description of the display devices DD-1, DD-2 and DD3 in embodiments with reference to FIG. 6 to FIG. 8, duplicate description made with reference to FIG. 1 to FIG. 5 will be omitted, and the following description will be focused on different points.

A display device DD-1 illustrated in FIG. 6 is different from the display device DD illustrated in FIG. 5 in that a contact hole CTH is defined by penetrating a pixel defining film PDL-1 of the display element layer DP-OEL-1, a hole transport region HTR-1 and an electron transport region ETR-1, and a lower auxiliary electrode BML, which is disposed on a base substrate SUB and includes a top surface exposed in the contact hole CTH, is further provided.

Referring to FIG. 6, in the display device DD-1 in an embodiment, an auxiliary opening SOH may be defined in the pixel defining film PDL-1 and separated in the first direction DR1 from the opening OH, in which the light-emitting region is disposed. The hole transport region HTR-1 and the electron transport region ETR-1 may be disposed extending to the inside of the auxiliary opening SOH. The contact hole CTH may be defined by penetrating the hole transport region HTR-1 and the electron transport region ETR-1.

The contact hole CTH is defined by penetrating the hole transport region HTR-1 and the electron transport region ETR-1, and the lower auxiliary electrode BML which is disposed on the base substrate SUB and includes a top surface exposed in the contact hole CTH may be further provided. The contact hole CTH may overlap the upper auxiliary electrode UML-1.

On the base substrate SUB, the lower auxiliary electrode BML may be disposed in the same layer as a layer in which the first electrode EL1 is disposed. On the base substrate SUB, the lower auxiliary electrode BML may be separated from the first electrode EL1 in the first direction DR1. The lower auxiliary electrode BML may electrically contact the second electrode EL2-1 of a light-emitting element OEL-1. The second electrode EL2-1 is disposed directly on the lower auxiliary electrode BML. In FIG. 6, one lower auxiliary electrode BML is disposed but the invention is not limited thereto. In an embodiment, the display device DD-1 in an embodiment may include a plurality of lower auxiliary electrodes disposed on the base substrate SUB, for example.

The lower auxiliary electrode BML may have a lower resistivity than that of the second electrode EL2-1. The lower auxiliary electrode BML and the upper auxiliary electrode UML-1 may include the same material as each other. In an embodiment, both the lower auxiliary electrode BML and the upper auxiliary electrode UML-1 may include silver, or may include copper, for example.

The lower auxiliary electrode BML may be formed or provided using various methods such as an inkjet printing method, a sputtering method, or vacuum deposition method.

The auxiliary opening SOH in an embodiment may be defined in the pixel defining film PDL-1 to overlap the upper auxiliary electrode UML. The hole transport region HTR-1 and the electron transport region ETR-1 may extend to the inside of the auxiliary opening SOH while following the shape of the auxiliary opening SOH. The contact hole CTH, which penetrates the hole transport region HTR-1 and the electron transport region ETR-1 extending to the inside of the auxiliary opening SOH, may be defined.

The second electrode EL2-1 may be disposed in the auxiliary opening SOH. The second electrode EL2-1 may extend to the inside of the auxiliary opening SOH while following the shape of the auxiliary opening SOH. The second electrode EL2-1 may extend in the first direction DR1 to overlap the contact hole CTH. The second electrode EL2-1 in the auxiliary opening SOH may be disposed directly on the lower auxiliary electrode BML. The second electrode EL2-1, and the lower auxiliary electrode BML which has a lower resistivity than that of the second electrode EL2-1 may be electrically connected to each other, and the resistance of the second electrode EL2-1 may thus be lowered, thereby reducing a voltage drop which occurs in the second electrode EL2-1. The reduction of the voltage drop in the second electrode EL2-1 leads to a decrease in stain which appears by the voltage drop in the display region DA (refer to FIG. 1), thereby improving the display quality of the display device DD-1.

The upper auxiliary electrode UML-1 in an embodiment may fill the auxiliary opening SOH on the second electrode EL2-1 which extends while following the shape of the auxiliary opening SOH. The second electrode EL2-1 and the upper auxiliary electrode UML-1 may be successively stacked in the auxiliary opening SOH. The upper auxiliary electrode UML-1 may be electrically connected to the second electrode EL2-1, and the resistance of the second electrode EL2-1 may thus be lowered, thereby reducing the voltage drop in the second electrode EL2-1.

In a display device DD-1 in an embodiment, the electrical connection characteristic may be improved because the second electrode EL2-1 and the lower auxiliary electrode BML are in closer contact with each other due to the weight of the upper auxiliary electrode UML-1 disposed on the second electrode EL2-1. The improvement in the electrical connection characteristic between the second electrode EL2-1 and the lower auxiliary electrode BML may reduce the resistance of the second electrode EL2-1, thereby reducing the voltage drop in the second electrode EL2-1. Therefore, the stain which appears by the voltage drop in the second electrode EL2-1 in the display region DA (refer to FIG. 1) is reduced, so that the display quality of the display device DD-1 in an embodiment may be improved.

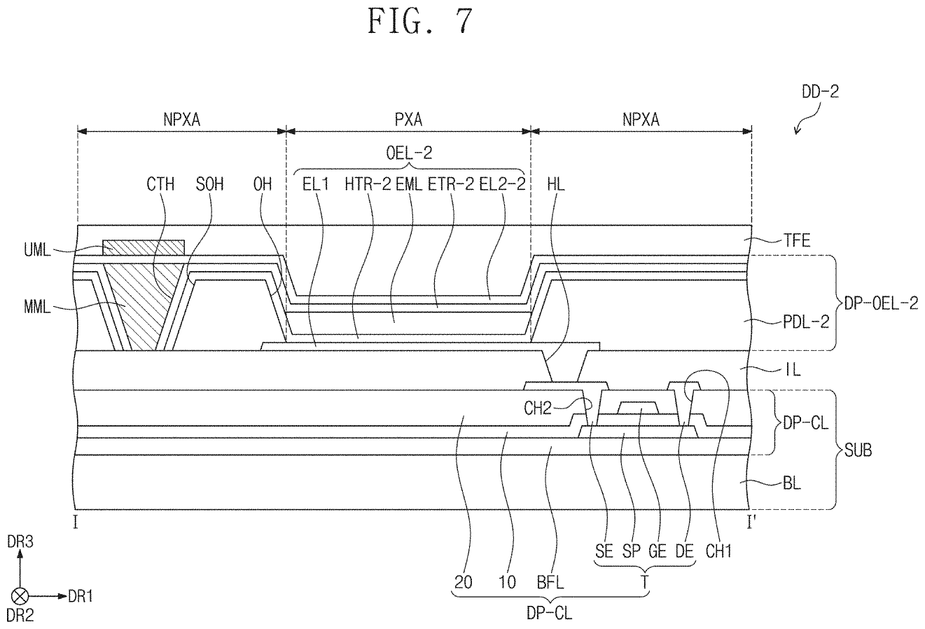

A display device DD-2 illustrated in FIG. 7 is different from the display device DD illustrated in FIG. 5 in that an intermediate auxiliary electrode MML which is disposed between the second electrode EL2-2 of a light-emitting element OEL-2 and the base substrate SUB is further provided.

Referring FIG. 7, the display device DD-2 in an embodiment may further include the intermediate auxiliary electrode MML which is disposed between the second electrode EL2-2 and the base substrate SUB. The intermediate auxiliary electrode MML may fill the auxiliary opening portion SOH. The second electrode EL2-2 may be disposed on top of the intermediate auxiliary electrode MML and have a flat shape. However, this is a mere example, and the invention is not limited thereto. The second electrode EL2-2 in an embodiment may extend in the first direction DR1 while following a concave portion (not illustrated) which is formed or provided by the intermediate auxiliary electrode MML and the auxiliary opening SOH.

The intermediate auxiliary electrode MML may have a lower resistivity than that of the second electrode EL2-2. The intermediate auxiliary electrode MML and the upper auxiliary electrode UML may include the same material as each other. In an embodiment, the intermediate auxiliary electrode MML and the upper auxiliary electrode UML may include silver or copper, for example.

In the display device DD-2 in an embodiment, the second electrode EL2-2 may be electrically connected to the intermediate auxiliary electrode MML having a lower resistivity than that of the second electrode EL2-2, and the resistance of the second electrode EL2-2 may thus be lowered, thereby reducing a voltage drop which occurs in the second electrode EL2-2. The reduction of the voltage drop in the second electrode EL2-2 leads to a decrease in stain which appears by the voltage drop in the display region DA (refer to FIG. 1), thereby improving the display quality of the display device DD-2. A hole transport region HTR-2 and an electron transport region ETR-2 may be disposed in an auxiliary opening SOH defined in a pixel defining film PDL-2 of a display element layer DP-OEL-2, and may contact an upper surface of an insulating layer IL through the auxiliary opening SOH.

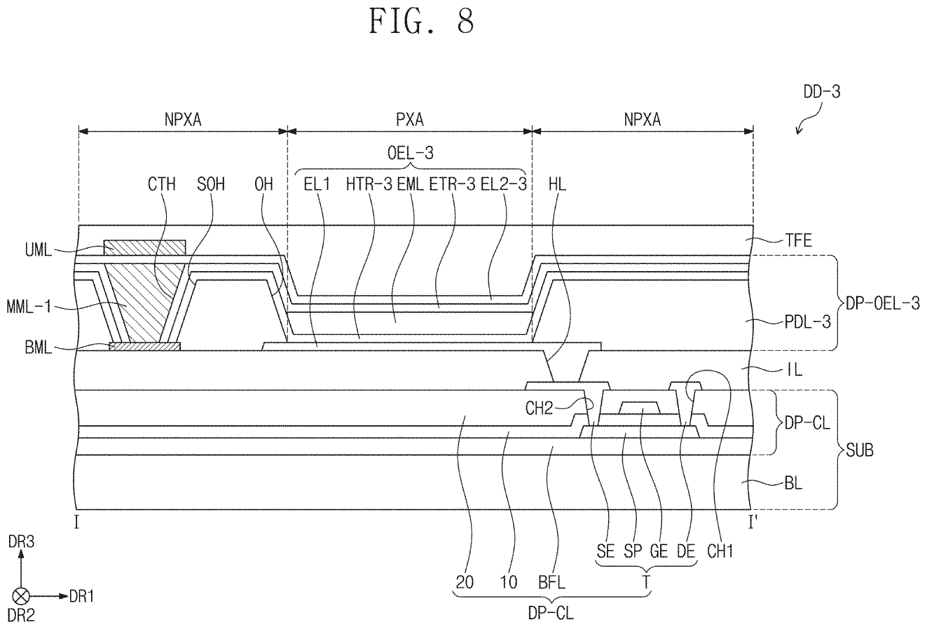

A display device DD-3 illustrated in FIG. 8 is different from the display device DD-2 illustrated in FIG. 7 in that a lower auxiliary electrode BML which is disposed between the base substrate SUB and the intermediate auxiliary electrode MML-1 is further provided.

Referring FIG. 8, the display device DD-3 in an embodiment may include the lower auxiliary electrode BML which is disposed between the base substrate SUB and the intermediate auxiliary electrode MML-1. The intermediate auxiliary electrode MML-1 may be disposed directly on the lower auxiliary electrode BML. The intermediate auxiliary electrode MML-1 and the lower auxiliary electrode BML may each have a lower resistivity than that of the second electrode EL2-3 of a light-emitting element OEL-3. The intermediate auxiliary electrode MML-1 and the lower auxiliary electrode BML may include the same material as each other. In an embodiment, the intermediate auxiliary electrode MML-1 and the lower auxiliary electrode BML may each include silver or copper, for example.

The display device DD-3 in an embodiment may include all of the lower auxiliary electrode BML, the intermediate auxiliary electrode MML-1, and the upper auxiliary electrode UML which are disposed to overlap each other. The lower auxiliary electrode BML, the intermediate auxiliary electrode MML-1, and the upper auxiliary electrode UML may each include a metal material which has a lower resistivity than that of the second electrode EL2-3. The intermediate auxiliary electrode MML-1, and the upper auxiliary electrode UML may include the same material, or at least one thereof may differ in material from the others.

In the display device DD-3 in an embodiment, the second electrode EL2-3 may be electrically connected to the intermediate auxiliary electrode MML-1 and the lower auxiliary electrode BML which have lower resistivity than that of the second electrode EL2-3. Therefore, the resistance of the second electrode EL2-3 may be lowered, thereby reducing a voltage drop which may occur in the second electrode EL2-3. The reduction of the voltage drop in the second electrode EL2-3 leads to a decrease in stain which appears by the voltage drop in the display region DA (refer to FIG. 1), thereby improving the display quality of the display device DD-3. A hole transport region HTR-3 and an electron transport region ETR-3 may be disposed in an auxiliary opening SOH defined in a pixel defining film PDL-3 of a display element layer DP-OEL-3, and may contact an upper surface of a lower auxiliary electrode BML through the auxiliary opening SOH.

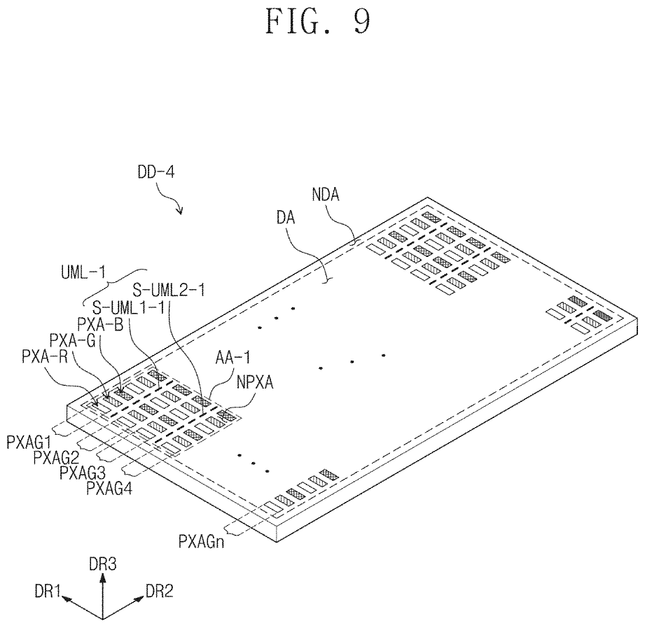

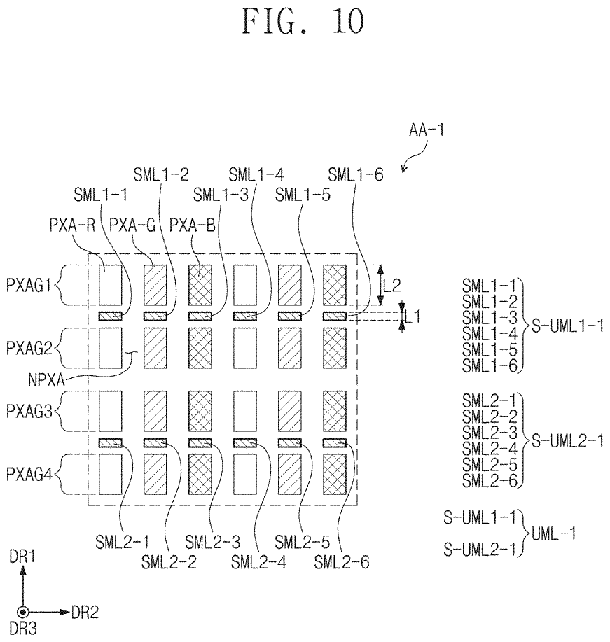

FIG. 9 is a perspective view of an embodiment of a display device DD-4. FIG. 10 is a plan view of a display device DD-4. FIG. 10 may be an enlarged plan view of an embodiment of a portion corresponding to region AA-1 in FIG. 9. In the description of the display device DD-4 in an embodiment with reference to FIG. 9 and FIG. 10, the duplicate description made with reference to FIG. 1 to FIG. 8 will be omitted, and the following description will be focused on different points.

The display device DD-4 illustrated in FIG. 9 and FIG. 10 is different from the display device illustrated in FIG. 1 to FIG. 8 in that an upper auxiliary electrode UML-1 includes a plurality of first sub-auxiliary electrodes SML1-1 to SML1-6 and a plurality of second sub-auxiliary electrodes SML2-1 to SML2-6 which are separated from each other in the second direction DR2.

Referring to FIG. 9 and FIG. 10, the upper auxiliary electrode UML-1 in an embodiment may include a first upper auxiliary electrode S-UML1-1 and a second upper auxiliary electrode S-UML2-1. The first upper auxiliary electrode S-UML1-1 may include the plurality of first sub-auxiliary electrodes SML1-1 to SML1-6. The second upper auxiliary electrode S-UML2-1 may include the plurality of second sub-auxiliary electrodes SML2-1 to SML2-6.

The first sub-auxiliary electrodes SML1-1 to SML1-6 may be separated from each other in the second direction DR2. FIG. 9 illustrates that intervals, at which the first sub-auxiliary electrodes SML1-1 to SML1-6 are separated from each other in the second direction DR2, are equal. However, this is a mere example, and an the invention is not limited thereto. In an embodiment, none of intervals, at which the first sub-auxiliary electrodes SML1-1 to SML1-6 are separated from each other in the second direction DR2, may be equal, or the intervals may be partially equal, for example.

The second sub-auxiliary electrodes SML2-1 to SML2-6 may be separated from each other in the second direction DR2. FIG. 9 illustrates that intervals, at which the second sub-auxiliary electrodes SML2-1 to SML2-6 are separated from each other in the second direction DR2, are equal. However, this is a mere example, and the invention is not limited thereto. In an embodiment, none of intervals, at which the second sub-auxiliary electrodes SML2-1 to SML2-6 are separated from each other in the second direction DR2, may be equal, or the intervals may be partially equal, for example.

The first sub-auxiliary electrodes SML1-1 to SML1-6 and the second sub-auxiliary electrodes SML2-1 to SML2-6 may each have a quadrangular (e.g., rectangular) shape in a plan view. The width L1 of each of the first sub-auxiliary electrodes SML1-1 to SML1-6 and the second sub-auxiliary electrodes SML2-1 to SML2-6 in the first direction DR1 may be less than the width L2 of each of the pixel groups PXAG1, PXAG2, PXAG3, PXAG4, . . . , PXAGn in the first direction DR1.

In FIG. 10, the first sub-auxiliary electrodes SML1-1 to SML1-6 and the second sub-auxiliary electrodes SML2-1 to SML2-6 each are illustrated to have a quadrangular (e.g., rectangular) shape in a plan view. However, this is a mere example, and the invention is not limited thereto. In an embodiment, the first sub-auxiliary electrodes SML1-1 to SML1-6 and the second sub-auxiliary electrodes SML2-1 to SML2-6 may each have a circular, an elliptical, a polygonal or a dot shape in a plan view, for example.

The first sub-auxiliary electrodes SML1-1 to SML1-6 may each be disposed between a first pixel group PXAG1 and a second pixel group PXAG2. The second sub-auxiliary electrodes SML2-1 to SML2-6 may each be disposed between a third pixel group PXAG3 and a fourth pixel group PXAG4. The second pixel group PXAG2 and the third pixel group PXAG3 may be disposed between the first sub-auxiliary electrodes SML1-1 to SML1-6 and the second sub-auxiliary electrodes SML2-1 to SML2-6.

FIG. 9 and FIG. 10 illustrate that, between the first sub-auxiliary electrodes SML1-1 to SML1-6 and the second sub-auxiliary electrodes SML2-1 to SML2-6, the pixel regions PXA-R, PXA-G and PXA-B are disposed in the first direction DR1 in one-to-one correspondence with the first sub-auxiliary electrodes SML1-1 to SML1-6 and the second sub-auxiliary electrodes SML2-1 to SML2-6, respectively. However, this is a mere example, the invention is not limited thereto. In an embodiment, between the first sub-auxiliary electrodes SML1-1 to SML1-6 and the second sub-auxiliary electrodes SML2-1 to SML2-6, the pixel regions PXA-R, PXA-G and PXA-B are disposed in many-to-one correspondence with the first sub-auxiliary electrodes SML1-1 to SML1-6 and the second sub-auxiliary electrodes SML2-1 to SML2-6, respectively, or the pixel regions PXA-R, PXA-G and PXA-B are disposed in one-to-many correspondence with the first sub-auxiliary electrodes SML1-1 to SML1-6 and the second sub-auxiliary electrodes SML2-1 to SML2-6 respectively, for example. In an alternative embodiment, in a plan view, the pixel regions PXA-R, PXA-G and PXA-B are disposed in the first direction DR1 such that at least a portion thereof does not correspond to the first sub-auxiliary electrodes SML1-1 to SML1-6 and the second sub-auxiliary electrodes SML2-1 to SML2-6. When the pixel regions PXA-R, PXA-G and PXA-B are disposed in the first direction DR1 in a plan view such that none thereof correspond to the first sub-auxiliary electrodes SML1-1 to SML1-6 and the second sub-auxiliary electrodes SML2-1 to SML2-6, the pixel regions PXA-R, PXA-G and PXA-B may be considered not to be disposed between the first sub-auxiliary electrodes SML1-1 to SML1-6 and the second sub-auxiliary electrodes SML2-1 to SML2-6.

In the display device DD-4 in an embodiment, the second electrode EL2 and the upper auxiliary electrode UML-1 which has a lower resistivity than that of the second electrode EL2 may be electrically connected to each other, and the resistance of the second electrode EL2 may thus be lowered, thereby reducing a voltage drop (IR drop) which occurs in the second electrode EL2. The reduction of the voltage drop in the second electrode EL2 leads to a decrease in stain which appears by the voltage drop in the display region DA (refer to FIG. 1), thereby improving the display quality of the display device DD-4.

In a display device in an embodiment, the second electrode may be electrically connected to the upper auxiliary electrode having a lower resistivity than that of the second electrode, and the resistance of the second electrode may thus be lowered, thereby reducing a voltage drop occurring in the second electrode. The reduction of the voltage drop in the second electrode results in a decrease in stain which appears by the voltage drop in the display region, thereby improving the display quality of the display device.

By embodiments, an upper auxiliary electrode having a low resistivity may be disposed on the second electrode to reduce a voltage drop, thereby providing a display device that exhibits excellent display quality.

Although the embodiments of the invention have been described, it is understood that the invention should not be limited to these embodiments but various changes and modifications may be made by one ordinary skilled in the art within the spirit and scope of the invention as hereinafter claimed.

What is claimed is:

1. A display device comprising:
a base substrate;
a pixel defining film which is disposed on the base substrate and in which an opening is defined;
a first electrode disposed on the base substrate and including a first surface facing the base substrate and a second surface opposite to the first surface and exposed in the opening;
a light-emitting layer disposed on the first electrode in the opening;
a hole transport region disposed between the first electrode and the light-emitting layer;
an electron transport region disposed on the light-emitting layer;
a second electrode disposed on the electron transport region and disposed extending above the pixel defining film; and
a first auxiliary electrode disposed on the second electrode not to overlap the light-emitting layer, and having a lower resistivity than a resistivity of the second electrode.

2. The display device of claim 1, wherein the first auxiliary electrode has a resistivity greater than about 0 ohm centimeter and equal to or less than about 4.4×10⁻⁶ ohm centimeter.

3. The display device of claim 2, wherein the first auxiliary electrode comprises silver (Ag) or copper (Cu).

4. The display device of claim 1, wherein the hole transport region and the electron transport region are disposed extending above the pixel defining film.

5. The display device of claim 4, further comprising a second auxiliary electrode disposed on the base substrate and including a first surface facing the base substrate and a second surface opposite to the first surface and exposed in a contact hole,
wherein an auxiliary opening is defined on the pixel defining film to overlap the first auxiliary electrode, and the contact hole is defined by penetrating the hole transport region and the electron transport region extending to an inside of the auxiliary opening.

6. The display device of claim 5, wherein the second electrode in the auxiliary opening is disposed directly on the second auxiliary electrode.

7. The display device of claim 6, wherein the first auxiliary electrode charges the auxiliary opening.

8. The display device of claim 5, further comprising an intermediate auxiliary electrode disposed between the second auxiliary electrode and the second electrode in the auxiliary opening, and having a lower resistivity than the resistivity of the second electrode.

9. The display device of claim 5, further comprising an intermediate auxiliary electrode which charges the auxiliary opening and having a lower resistivity than the resistivity of the second electrode,
wherein the second electrode is disposed directly on the intermediate auxiliary electrode.

10. A display device including a plurality of pixel groups which are arranged in a first direction and separated from each other, and each of which includes a plurality of light-emitting regions arranged in a second direction perpendicular to the first direction, the display device comprising:
a base substrate;
a pixel defining film which is disposed on the base substrate and in which an opening corresponding to each of the plurality of light-emitting regions is defined;
a first electrode disposed on the base substrate and patterned corresponding to each of the plurality of light-emitting regions;
a light-emitting layer disposed on the first electrode substrate and patterned corresponding to each of the plurality of light-emitting regions;
a hole transport region disposed between the first electrode and the light-emitting layer;
an electron transport region disposed on the light-emitting layer;
a second electrode disposed on the electron transport region; and
at least one first auxiliary electrode disposed on the second electrode not to overlap the light-emitting layer, and having a lower resistivity than a resistivity of the second electrode.

11. The display device of claim 10, wherein, in a plan view, the at least one first auxiliary electrode is disposed between the plurality of pixel groups, and
the at least one first auxiliary electrode has a line shape extending in the second direction.

12. The display device of claim 10, wherein the at least one first auxiliary electrode is provided in plural,
a plurality of first auxiliary electrodes is respectively arranged between the plurality of pixel groups,
the plurality of first auxiliary electrodes respectively comprises sub-auxiliary electrodes separated from each other in the second direction, and
the plurality of first auxiliary electrodes each has a dot shape.

13. The display device of claim 10, wherein the at least one first auxiliary electrode is provided in plural, and
in a plan view, a plurality of first auxiliary electrodes is separated in the first direction with at least one of the plurality of pixel groups disposed therebetween.

14. The display device of claim 10, wherein the plurality of light-emitting regions comprise:
a first light-emitting region which emits first light;
a second light-emitting region which emits second light having a wavelength different from a wavelength of the first light; and
a third light-emitting region which emits third light having a wavelength different from the wavelengths of the first light and the second light,
the plurality of light-emitting regions being alternately arranged in an order of the first light-emitting region to the third light-emitting region in respective pixel groups of the plurality of pixel groups.

15. The display device of claim 10, wherein the plurality of pixel groups each comprises light-emitting regions of the plurality of light-emitting regions and a non-light-emitting region disposed between the light-emitting regions, and
the hole transport region, the electron transport region and the second electrode are disposed as a common layer in the light-emitting regions and the non-light-emitting region.

16. A display device including a plurality of light-emitting regions and a non-light-emitting region disposed between the light-emitting regions, the display device comprising:
a base substrate;
a pixel defining film which is disposed on the base substrate and in which an opening corresponding to each of the plurality of light-emitting regions is defined;
a first electrode disposed on the base substrate by being patterned corresponding to each of plurality of light-emitting regions and including a first surface facing the base substrate and a second surface opposite to the first surface and exposed in the opening;
a light-emitting layer disposed on the first electrode substrate;
a hole transport region disposed between the first electrode and the light-emitting layer;
an electron transport region disposed on the light-emitting layer;
a second electrode disposed as a common layer in the plurality of light-emitting region and the non-light-emitting region; and
a first auxiliary electrode disposed on the second electrode in the non-light-emitting region and having a lower resistivity than a resistivity of the second electrode.

17. The display device of claim 16, wherein the hole transport region and the electron transport region are disposed as a common layer in the plurality of light-emitting regions and the non-light-emitting region.

18. The display device of claim 16, further comprising a second auxiliary electrode separated from the first electrode on the base substrate and disposed in a same layer as a layer in which the first electrode is disposed.

19. The display device of claim 18, wherein
an auxiliary opening is defined in the pixel defining film to overlap the first auxiliary electrode,
a contact hole is defined to penetrate the hole transport region and the electron transport region extending to an inside of the auxiliary opening, and
the second electrode is disposed directly on a first surface of the second auxiliary electrode in the contact hole, the first surface of the second auxiliary electrode facing a second surface of the second auxiliary electrode facing the base substrate.

20. The display device of claim 18, further comprising an intermediate auxiliary electrode disposed between the second auxiliary electrode and the second electrode, and having a lower resistivity than the resistivity of the second electrode.
